(19) United States
(12) Patent Application Publication
(10) Pub. No.: US 2026/0093882 A1
(43) Pub. Date: Apr. 2, 2026

(54) TEST POINT INSERTION AT REGISTER TRANSFER LEVEL

(71) Applicant: Siemens Industry Software Inc., Plano, TX (US)

(72) Inventors: Nilanjan Mukherjee, Wilsonville, OR (US); Oussama Laouamri, Wilsonville, OR (US)

(73) Assignee: Siemens Industry Software Inc., Plano, TX (US)

(21) Appl. No.: 18/903,865

(22) Filed: Oct. 1, 2024

(51) Int. Cl. G06F 30/327

(52) U.S. Cl. CPC G06F 30/327

(57) ABSTRACT

Various aspects of the present disclosed technology relate to techniques for test point insertion at register transfer level for a circuit design. A quick logic synthesis process is performed on an RTL circuit design to generate a gate-level netlist. Gate-level nodes in the gate-level netlist are back-annotated to corresponding locations in the RTL circuit design. Editable areas in the gate-level netlist are determined based on the back-annotation. A test point analysis process is performed on the gate-level netlist to determine gate-level locations for test point insertion in the editable areas. RTL locations for test point insertion in the RTL circuit design corresponding to the gate-level locations for test point insertion are determined based on the back-annotating result. Test points are inserted at the RTL locations for test point insertion to derive a modified RTL circuit design.

### FIELD OF THE DISCLOSED TECHNOLOGY

The present disclosed technology relates to the field of circuit design and test. Various implementations of the disclosed technology may be particularly useful for speeding up the overall design cycle by shifting testability analysis and test point insertion to RTL (register transfer level).

### BACKGROUND OF THE DISCLOSED TECHNOLOGY

Exponential growth in size and complexity of integrated circuits, coupled with heterogenous integration of multiple dies into a single package, poses new challenges for integrated circuit design and integration. The demand for stringent quality and reliability has also been on the rise, as integrated circuits are being deployed in mission-critical applications such as automotive, cloud-based services, the fifth generation of mobile networks, and others. Thus, there is an urgent need for efficient EDA (electronic design automation) tools and flows for circuit designs that can address the challenges related to power, performance, area, and testability (PPAT) optimization in an efficient manner.

In a typical circuit design flow, design-for-test implementation is performed at the gate-level after the functional logic is finalized and the circuit design goes through the logic synthesis step. Although adding logic at the gate level is more robust due to the availability of circuit structural information, implementing such a flow for advanced technology nodes can impact performance, power, and area because they are optimized during and immediately after the logic synthesis step. Any changes at the gate-level will require re-optimization of various design parameters, thereby increasing the design-cycle time. Consequently, the industry has been trying to adopt a “Shift-Left” strategy, moving many of the design-for-test tasks to the register transfer level (RTL).

Test point insertion (TPI) is a widely used deign-for-test technique. It can reduce the test pattern count and thus the overall manufacture test costs. Moreover, test point insertion can improve the random-pattern test coverage and thus is widely used for in-system logic BIST (built-in self-test). In automotive applications, for example, logic BIST is used as safety monitors and becomes part of user functional logic. As such, logic BIST must be verified at the RTL design phase. Meanwhile, ASIL (Automotive Safety Integrity Level) certification requires that high logic BIST test coverage be achieved within limited test time, resulting in the need for many test points and a large number of design iterations. The design period for safety function implementation thus tends to be long. Reducing the design period by moving test point insertion to RTL is highly desirable. Identifying test points at RTL, however, remains a challenge due to the lack of structural information.

### BRIEF SUMMARY OF THE DISCLOSED TECHNOLOGY

Various aspects of the present disclosed technology relate to techniques for test point insertion at register transfer level for a circuit design. In one aspect, there is a method comprising: receiving an RTL (register-transfer-level) circuit design; performing a quick logic synthesis process on the RTL circuit design to generate a gate-level netlist; back-annotating gate-level nodes in the gate-level netlist to corresponding locations in the RTL circuit design; determining editable areas in the gate-level netlist based on the back-annotating gate-level nodes; performing a test point analysis process on the gate-level netlist to determine gate-level locations for test point insertion in the editable areas; determining RTL locations for test point insertion in the RTL circuit design corresponding to the gate-level locations for test point insertion based on the back-annotating gate-level nodes; and storing information of the RTL locations for test point insertion for modifying the RTL circuit design.

The method may further comprise: inserting test points at the RTL locations for test point insertion to derive a modified RTL circuit design; and performing a full logic synthesis process on the modified RTL circuit design to generate a technology-mapped and fully optimized gate-level netlist. The method may still further comprise: inserting additional test points into the technology-mapped and fully optimized gate-level netlist based on a further test point analysis process.

The method may further comprise: performs an RTL complexity analysis based on the information of the RTL locations for test point insertion to provide information for designers to adjust the RTL circuit design; and adjusting the RTL circuit design based on the information for designers to adjust the RTL circuit design.

The quick Logic synthesis process may comprise: mapping to a generic library. The gate-level netlist may be flattened and represented as a Directed Acyclic Graph (DAG).

The editable areas may comprise: gate-level nodes that are directly mapped to RTL nets; and gate-level nodes that are directly mapped to RTL expression or sub-expression boundaries. The editable areas may further comprise: gate-level nodes that are mapped to RTL locations belonging to functional block objects.

In another aspect, there is one or more computer-readable media storing computer-executable instructions for causing one or more processors to perform the above method.

In still another aspect, there is a system, comprising: one or more processors, the one or more processors programmed to perform the above method.

Certain inventive aspects are set out in the accompanying independent and dependent claims. Features from the dependent claims may be combined with features of the independent claims and with features of other dependent claims as appropriate and not merely as explicitly set out in the claims.

Certain objects and advantages of various inventive aspects have been described herein above. Of course, it is to be understood that not necessarily all such objects or advantages may be achieved in accordance with any particular embodiment of the disclosed technology. Thus, for example, those skilled in the art will recognize that the disclosed technology may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

FIG. 1 illustrates an example of a computing device that may be used to implement various embodiments of the disclosed technology.

FIG. 2 illustrates an example design flow involving design-for-test implementation.

FIG. 3 illustrates an RTL test point tool that may be implemented according to various embodiments of the disclosed technology.

FIG. 4 illustrates a flowchart showing a process of RTL test point insertion that may be implemented according to various examples of the disclosed technology.

FIG. 5 illustrates an example of a small piece of System Verilog RTL code.

FIG. 6 illustrates a flattened directed acyclic graph (DAG) representation derived by transforming the System Verilog RTL code shown in FIG. 5.

FIG. 7 illustrates a one-to-one correspondence between some of the DAG nodes shown in FIG. 6 and the back-annotated RTL locations shown in FIG. 5 which are highlighted.

FIG. 8 illustrates an example of conflict-aware test points.

FIG. 9 illustrates an example test point analysis for reducing ATPG pattern counts and scan data volume.

FIG. 10 illustrates an example of LBIST test points.

FIG. 11 illustrates an example of an overall test point analysis process that may be implemented according to various examples of the disclosed technology.

FIG. 12 illustrates an example of a control test point (highlighted) inserted at a 1-bit output of a logical expression.

FIG. 13 illustrates an example of two control test points inserted at the output of an expression of 4-bits.

FIG. 14 illustrates an example of an observation test point inserted at the output of a 1-bit expression.

FIG. 15A illustrates an example of an RTL design before a control test point is inserted into a visible net.

FIG. 15B illustrates an example of the RTL design shown in FIG. 15A but after a control test point is inserted into a visible net.

FIG. 16 illustrates the benefits of RTL test point insertion in terms of total area overhead percentage for two industry designs D1 and D2.

### DETAILED DESCRIPTION OF THE DISCLOSED TECHNOLOGY

### General Considerations

Various aspects of the present disclosed technology relate to techniques for test point insertion at register transfer level for a circuit design. In the following description, numerous details are set forth for the purpose of explanation. However, one of ordinary skill in the art will realize that the disclosed technology may be practiced without the use of these specific details. In other instances, well-known features have not been described in detail to avoid obscuring the present disclosed technology.

Some of the techniques described herein can be implemented in software instructions stored on a computer-readable medium, software instructions executed on a computer, or some combination of both. Some of the disclosed techniques, for example, can be implemented as part of an electronic design automation (EDA) tool. Such methods can be executed on a single computer or on networked computers.

Although the operations of the disclosed methods are described in a particular sequential order for convenient presentation, it should be understood that this manner of description encompasses rearrangements, unless a particular ordering is required by specific language set forth below. For example, operations described sequentially may in some cases be rearranged or performed concurrently. The detailed description sometimes uses terms like “perform”, “back-annotate”, “associate”, and “determine” to describe the disclosed methods/systems. Such terms are high-level descriptions of the actual operations that are performed. The actual operations that correspond to these terms will vary depending on the particular implementation and are readily discernible by one of ordinary skill in the art.

As used in this disclosure, the singular forms “a,” “an,” and “the” include the plural forms unless the context clearly dictates otherwise. Additionally, the term “includes” means “comprises.” Moreover, unless the context dictates otherwise, the term “coupled” means electrically or electromagnetically connected or linked and includes both direct connections or direct links and indirect connections or indirect links through one or more intermediate elements not affecting the intended operation of the circuit.

Also, as used herein, the term “design” is intended to encompass data describing an entire integrated circuit device. This term also is intended to encompass a smaller group of data describing one or more components of an entire device, however, such as a portion of an integrated circuit device. Still further, the term “design” also is intended to encompass data describing more than one microdevice, such as data to be used to form multiple microdevices on a single wafer.

### Illustrative Operating Environment

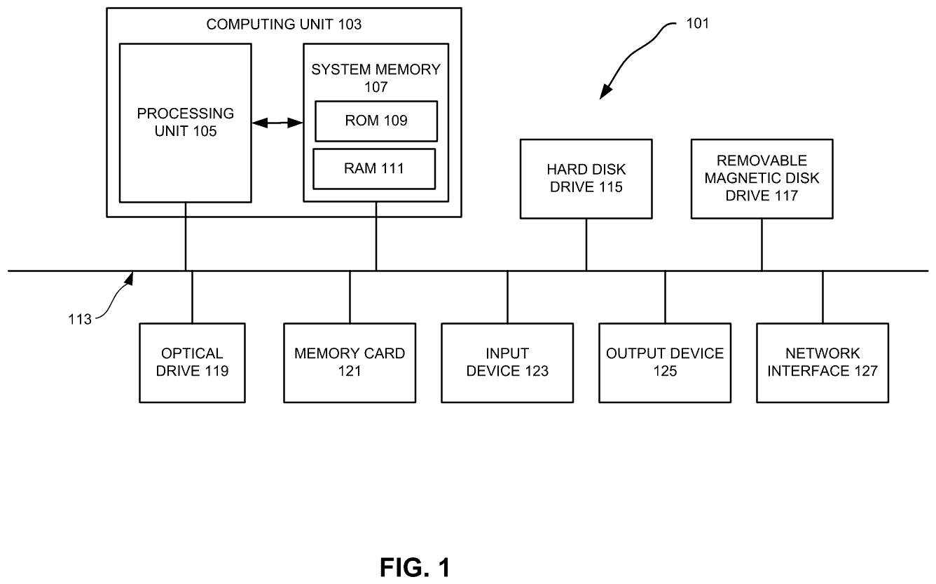

Various examples of the disclosed technology may be implemented through the execution of software instructions by a computing device, such as a programmable computer. Accordingly, FIG. 1 shows an illustrative example of a computing device 101. As seen in this figure, the computing device 101 includes a computing unit 103 with a processing unit 105 and a system memory 107. The processing unit 105 may be any type of programmable electronic device for executing software instructions, but it will conventionally be a microprocessor. The system memory 107 may include both a read-only memory (ROM) 109 and a random access memory (RAM) 111. As will be appreciated by those of ordinary skill in the art, both the read-only memory (ROM) 109 and the random access memory (RAM) 111 may store software instructions for execution by the processing unit 105.

The processing unit 105 and the system memory 107 are connected, either directly or indirectly, through a bus 113 or alternate communication structure, to one or more peripheral devices. For example, the processing unit 105 or the system memory 107 may be directly or indirectly connected to one or more additional memory storage devices, such as a “hard” magnetic disk drive 115, a removable magnetic disk drive 117, an optical disk drive 119, or a flash memory card 121. The processing unit 105 and the system memory 107 also may be directly or indirectly connected to one or more input devices 123 and one or more output devices 125. The input devices 123 may include, for example, a keyboard, a pointing device (such as a mouse, touchpad, stylus, trackball, or joystick), a scanner, a camera, and a microphone. The output devices 125 may include, for example, a monitor display, a printer and speakers. With various examples of the computer 101, one or more of the peripheral devices 115-125 may be internally housed with the computing unit 103. Alternately, one or more of the peripheral devices 115-125 may be external to the housing for the computing unit 103 and connected to the bus 113 through, for example, a Universal Serial Bus (USB) connection.

With some implementations, the computing unit 103 may be directly or indirectly connected to one or more network interfaces 127 for communicating with other devices making up a network. The network interface 127 translates data and control signals from the computing unit 103 into network messages according to one or more communication protocols, such as the transmission control protocol (TCP) and the Internet protocol (IP). Also, the interface 127 may employ any suitable connection agent (or combination of agents) for connecting to a network, including, for example, a wireless transceiver, a modem, or an Ethernet connection. Such network interfaces and protocols are well known in the art, and thus will not be discussed here in more detail.

It should be appreciated that the computer 101 is illustrated as an example only, and it is not intended to be limiting. Various embodiments of the disclosed technology may be implemented using one or more computing devices that include the components of the computer 101 illustrated in FIG. 1, which include only a subset of the components illustrated in FIG. 1, or which include an alternate combination of components, including components that are not shown in FIG. 1. For example, various embodiments of the disclosed technology may be implemented using a multi-processor computer, a plurality of single and/or multiprocessor computers arranged into a network, or some combination of both.

### Design Flow and Test Point Insertion's Impact

Electronic circuits, such as integrated circuits, are used in a variety of products, from automobiles to smart phones to computers. Designing and fabricating these circuit devices typically involves many steps, known as a “design flow.” The particular steps of a design flow often are dependent upon the type of integrated circuit being designed, its complexity, the design team, and the integrated circuit fabricator or foundry that will manufacture the circuit.

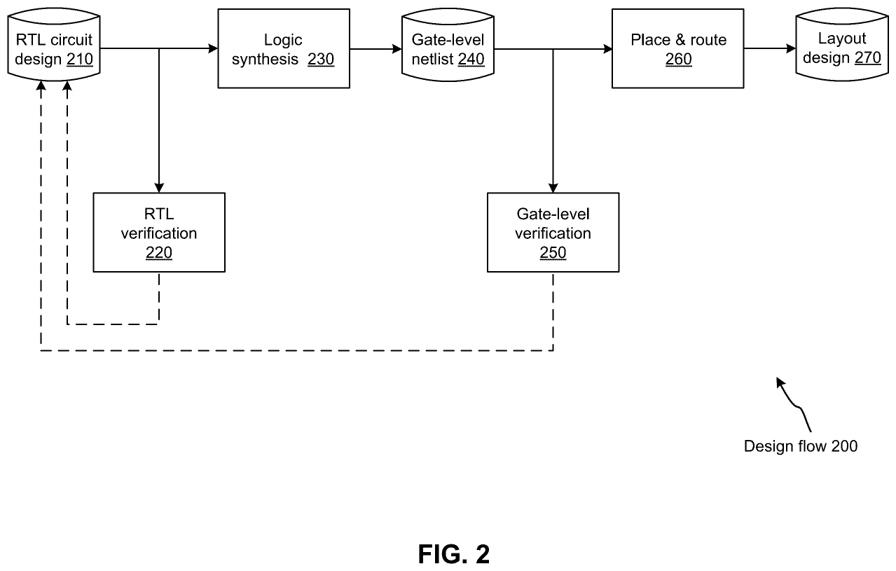

Several steps are common to most design flows. FIG. 2 illustrates an example design flow 200 involving design-for-test implementation. Initially, the specification for the new circuit is described at an abstract level as an RTL circuit design 210. Here, the type of abstract description is a register transfer level (RTL) description of the circuit. With this type of description, the circuit is defined in terms of both the exchange of signals between hardware registers and the logical operations that are performed on those signals. RTL constructs are the basic building blocks used in digital circuit design to represent the functionality and structure of a circuit. Common RTL constructs include registers, combinational logic, sequential logic, state machines, control and data path elements, and conditional statements. An RTL object refers to a specific instance or element in the RTL design. RTL designs typically employ a hardware description language (HDL) (sometimes also referred to as hardware design language or hardware definition language). The “very high speed integrated circuit hardware description language” (VHDL) or the Verilog language are two example hardware description languages.

The RTL circuit design 210 is then analyzed at an RTL verification step 220 to confirm that the logic incorporated into the RTL circuit design 210 will accurately perform the functions desired for the circuit. A key part of the RTL verification step is functional verification. Logic simulation is one of the tools used for functional verification. As noted above, designing hardware today involves writing a program in the hardware description language. A simulation process may be performed by running that program on a computer. Such an electronic design simulator can determine what the various states of an electronic design would be when presented with some input stimulus.

Software-based simulation, however, may be too slow for large complex designs such as SoC (System-on-Chip) designs. The speed of execution of a simulator drops significantly as the design size increases due to cache misses and memory swapping. Emulation and prototyping significantly increase verification productivity by employing reconfigurable hardware modeling devices including emulators and prototyping devices. Field programmable gate arrays (FPGAs)-based emulators and prototyping devices rely on an actual silicon implementation and perform circuit verification generally in parallel as the circuit design will execute in a real device. By contrast, a simulator performs circuit verification by executing the hardware description code serially. The different styles of execution can lead to orders of magnitude differences in execution time.

After the accuracy of the RTL circuit design 210 is confirmed, it is converted, by synthesis software, into a gate-level netlist 240. The gate-level netlist 240 describes the specific electronic devices such as logic gates and latches that will be used in the circuit, along with their interconnections. The conversion from an RTL behavior description (the RTL circuit design 210) to a device representation (the gate-level netlist 240) is shown as a logic synthesis step 230 in FIG. 2. Logic synthesis typically includes translation, technology-independent optimization, technology mapping, and technology-dependent optimization. Translation includes parsing and elaborating which analyze the hardware description language code and translates it into a set of Boolean expressions that represent the circuit's logic. Technology-independent optimization optimizes the Boolean expressions without taking into account the target technology (such as the physical constraints of the FPGA or ASIC). In technology-independent optimization, logic complexity is minimized by simplifying Boolean functions and reducing the number of gates. Technology mapping maps the logic onto the target technology's available gates and cells, which generates a netlist comprising specific gates, multiplexers, flip-flops, and other primitives available in the target library. Technology-dependent optimization includes timing optimization and area and power optimization. In timing optimization, timing constraints are applied to ensure that the design meets specific timing requirements, such as clock frequency and data path delays. Along with timing, the design is optimized for area to reduce the number of gates or cells and power consumption to minimize switching activity and static power. Trade-offs may be necessary between timing, area, and power, depending on the design's priorities.

The relationships between the electronic devices are then analyzed to confirm that the circuit described by the device design will correctly perform the desired functions. This step is shown as a gate-level verification step 250 in FIG. 2. Gate-level functional verification may include gate-level simulation, formal verification, static timing analysis and power-aware verification. Equivalence checking, a main part of formal verification, ensures that the gate-level netlist 240 is functionally equivalent to the RTL circuit design 210. Static timing analysis ensures that the gate-level netlist 240 meets the timing constraints (e.g., setup, hold, clock skew, etc.) without actually simulating the design. Power-aware verification verifies the power-related aspects of the synthesized design, such as power gating, clock gating, and low-power modes.

Once the various verifications are completed, the design is again transformed, this time from the gate-level netlist 240 into a physical design (a layout design 270) that describes specific geometric elements. The transformation step is shown as a place & route step 260 in FIG. 2. The geometric elements in the layout design 270, which typically are polygons, define the shapes that will be created in various layers of material to manufacture the circuit. For digital circuits, automated place and route tools will be used to define the physical layouts, especially of wires that will be used to interconnect the circuit devices. Each layer of the microcircuit will have a corresponding layer representation in the layout design, and the geometric shapes described in a layer representation will define the relative locations of the circuit elements that will make up the circuit device. For example, shapes in the layer representation of a metal layer will define the locations of the metal wires used to connect the circuit devices. Custom layout editors allow a designer to custom design the layout, which is mainly used for analog, mixed-signal, RF, and standard-cell designs. Integrated circuit layout descriptions can be provided in many different formats. The Graphic Data System II (GDSII) format is a popular format for transferring and archiving two-dimensional graphical IC layout data. A newer format is the OASIS (Open Artwork System Interchange Standard).

Design-for-test implementation is typically done at the gate-level after the functional logic is finalized and the design goes through the logic synthesis step 230. Many tasks in design-for-test implementation involve insertion of test instruments. Any changes at the gate-level will require re-optimization of various design parameters, thereby increasing the design-cycle time. Designers and design-for-test engineers are reluctant to introduce any design changes post-synthesis as it can impact the overall quality metrics of the design. Consequently, the industry has been adopting a “Shift-Left” strategy, where many of the design-for-test tasks are implemented and validated at RTL. Some of these tasks include running design-for-test-related design rule checks (DRCs), fixing the design to make it scan-friendly, performing design-for-test analysis, and insertion of test instruments such as built-in self-test, test compression, boundary-scan, and in-system test controllers in RTL.

Quite a few tasks, however, are still executed as part of the logic synthesis step or on gate-level designs. Scan stitching, automatic test pattern generation (ATPG), and test point insertion are among them. In a basic scan testing scheme, all or most of internal sequential state elements (latches, flip-flops, et al.) in a circuit design are made controllable and observable via a serial interface. These functional state elements are usually replaced with dual-purpose state elements called scan cells. Scan cells are connected together to form scan chains - serial shift registers for shifting in test patterns and shifting out test responses. This process is referred to as scan stitching. Test patterns are typically generated through an ATPG process, comprising: fault insertion, fault activation and fault propagation. Fault insertion identifies a fault site. Fault activation establishes a signal value at the fault site opposite that produced by the fault (e.g., for a stuck-at-0 fault, the fault activation process will try to establish a logic ‘1’ at that site). Fault propagation propagates the fault effect (e.g., stuck at 0) forward by sensitizing a path from a fault site to a scan cell or a primary output. Test point insertion are often employed to minimize the total number of test patterns and increase the fault coverage. Test point insertion algorithms can select hard-to-control and hard-to-observe sites or detection-conflict sites to insert control and observation points. When active, a control point forces a circuit's node to a specific logic value, whereas an observation point acts as a pseudo-primary output. All the above three processes need circuit structural information for robust implementation and thus are still mainly performed at the gate level.

As noted previously, test point insertion at the gate level can impact the optimized design. Adding a control points (CP) often involves inserting an AND/OR gate in the functional path, which can affect timing optimization. Adding an observe point (OP) usually involves adding the fan-out of a particular node, which can impact the drive strength of a gate and thus timing optimization. Test points also require scan cells to drive them, which can have an impact on the total area overhead. Due to all these characteristics, re-optimization can be required after test point insertion, increasing the design-cycle time.

### RTL Test Point Tool

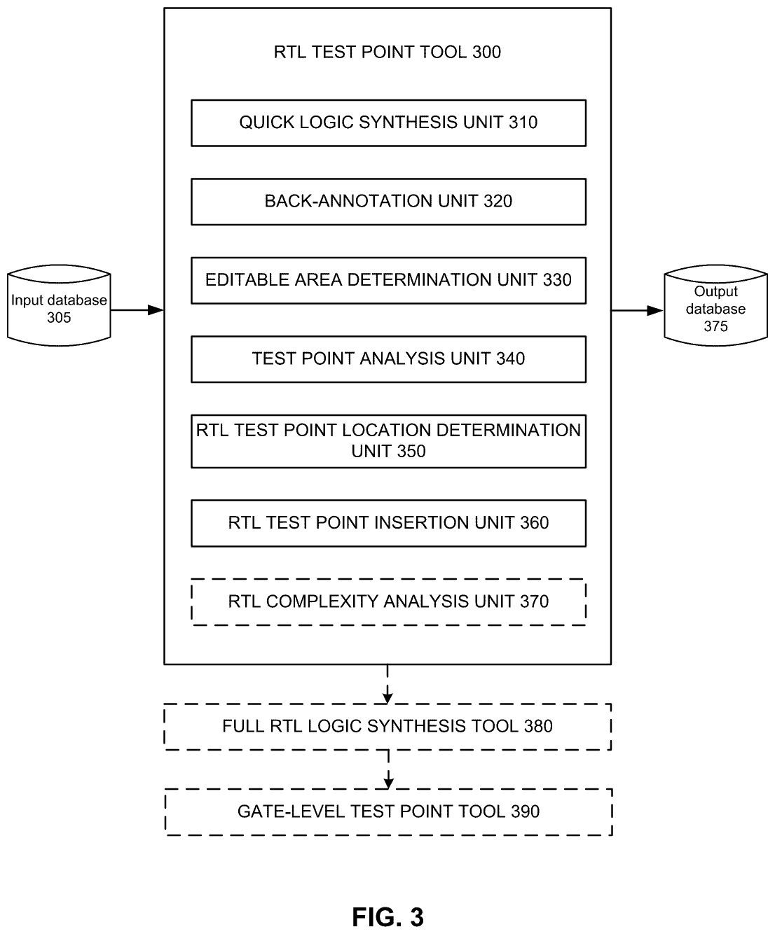

FIG. 3 illustrates an example of an RTL test point tool 300 that may be implemented according to various embodiments of the disclosed technology. As seen in this figure, the RTL test point tool 300 includes a quick logic synthesis unit 310, a back-annotation unit 320, an editable area determination unit 330, a test point analysis unit 340, an RTL test point location determination unit 350, and an RTL test point insertion unit 360. Various implementations of the RTL test point tool 300 may cooperate with (or incorporate) one or more of an RTL complexity analysis unit 370, a full RTL logic synthesis tool 380, a gate-level test point tool 390, an input database 305 and an output database 375. The full RTL logic synthesis tool 380 and the quick logic synthesis unit 310 may share some components.

As will be discussed in more detail below, the RTL test point tool 300 can receive, from the input database 305, an RTL (register-transfer-level) circuit design. The quick logic synthesis unit 310 can perform a quick logic synthesis process on the RTL circuit design to generate a gate-level netlist. The back-annotation unit 320 can back-annotate gate-level node in the gate-level netlist to corresponding locations in the RTL circuit design. The editable area determination unit 330 can determine editable areas in the gate-level netlist based on the back-annotating operation. The test point analysis unit 340 can perform a test point analysis process on the gate-level netlist to determine gate-level locations for test point insertion in the editable areas. The RTL test point location determination unit 350 can determine RTL locations for test point insertion in the RTL circuit design based on the back-annotating operation. The RTL test point tool 300 can store information of the RTL locations for test point insertion for modifying the RTL circuit design in the output database 375.

The RTL test point insertion unit 360 can insert test points at the RTL locations for test point insertion to derive a modified RTL circuit design. The full RTL logic synthesis tool 380 can perform a full logic synthesis process on the modified RTL circuit design to generate a technology-dependently-optimized gate-level netlist. The gate-level test point tool 390 can insert additional test points into the technology-dependently-optimized gate-level netlist based on a further test point insertion analysis process. The RTL complexity analysis unit 370 can perform an RTL complexity analysis to provide information for designers to adjust the RTL circuit design.

As previously noted, various examples of the disclosed technology may be implemented by one or more computing systems, such as the computing system illustrated in FIG. 1. Accordingly, one or more of the quick logic synthesis unit 310, the back-annotation unit 320, the editable area determination unit 330, the test point analysis unit 340, the RTL test point location determination unit 350, the RTL test point insertion unit 360, the RTL complexity analysis unit 370, the full RTL logic synthesis tool 380, and the gate-level test point tool 390 may be implemented by executing programming instructions on one or more processors in one or more computing systems, such as the computing system illustrated in FIG. 1. Correspondingly, some other embodiments of the disclosed technology may be implemented by software instructions, stored on a non-transitory computer-readable medium, for instructing one or more programmable computers/computer systems to perform the functions of one or more of the quick logic synthesis unit 310, the back-annotation unit 320, the editable area determination unit 330, the test point analysis unit 340, the RTL test point location determination unit 350, the RTL test point insertion unit 360, the RTL complexity analysis unit 370, the full RTL logic synthesis tool 380, and the gate-level test point tool 390. As used herein, the term “non-transitory computer-readable medium” refers to computer-readable medium that are capable of storing data for future retrieval, and not propagating electro-magnetic waves. The non-transitory computer-readable medium may be, for example, a magnetic storage device, an optical storage device, or a solid state storage device.

It also should be appreciated that, while the quick logic synthesis unit 310, the back-annotation unit 320, the editable area determination unit 330, the test point analysis unit 340, the RTL test point location determination unit 350, the RTL test point insertion unit 360, the RTL complexity analysis unit 370, the full RTL logic synthesis tool 380, and the gate-level test point tool 390 are shown as separate units in FIG. 1, a single computer (or a single processor within a master computer) or a single computer system may be used to implement some or all of these units at different times, or components of these units at different times.

With various examples of the disclosed technology, the input database 305 and the output database 375 may be implemented using any suitable computer readable storage device. That is, either of the input database 305 and the output database 375 may be implemented using any combination of computer readable storage devices including, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable storage devices may also include magnetic cassettes, magnetic tapes, magnetic disks or other magnetic storage devices, holographic storage devices, or any other non-transitory storage medium that can be used to store desired information. While the input database 305 and the output database 375 are shown as separate units in FIG. 3, a single data storage medium may be used to implement some or all of these databases.

### RTL Test Point Insertion

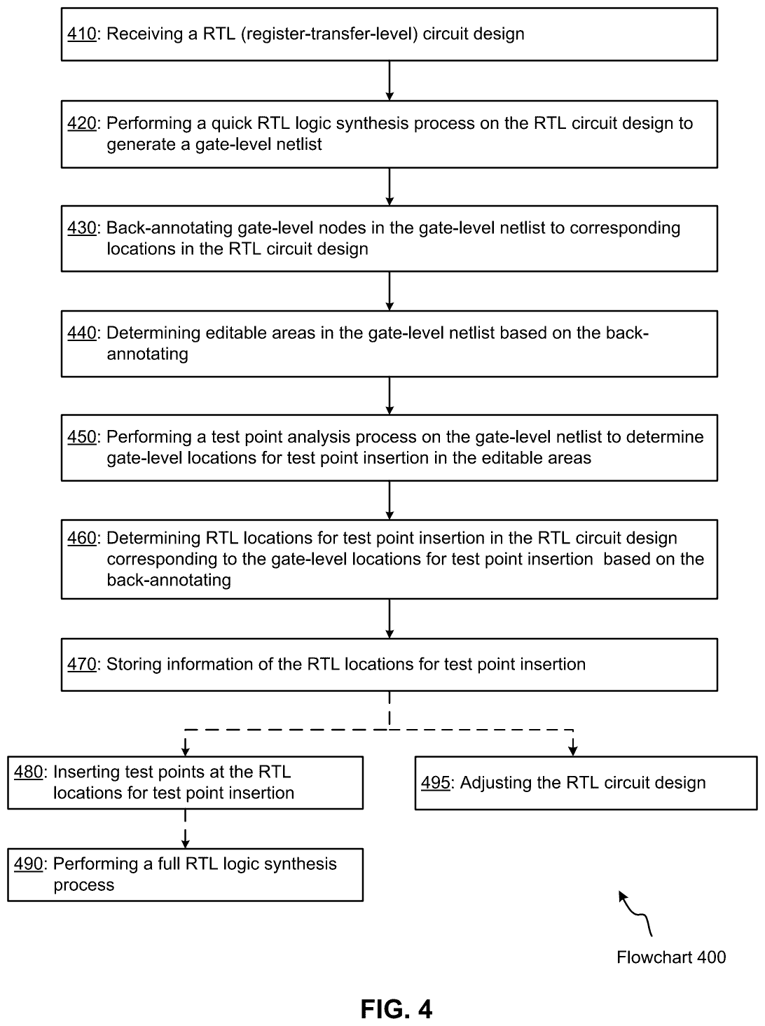

FIG. 4 illustrates a flowchart 400 showing a process of RTL test point insertion that may be implemented according to various examples of the disclosed technology. For ease of understanding, methods of RTL test point insertion that may be employed according to various embodiments of the disclosed technology will be described with reference to the RTL test point tool 300 in FIG. 3 and the flow chart 400 illustrated in FIG. 4. It should be appreciated, however, that alternate implementations of an RTL test point tool may be used to perform the methods of RTL test point insertion illustrated by the flow chart 400 according to various embodiments of the disclosed technology. Likewise, the RTL test point tool 300 may be employed to perform other methods of RTL test point insertion according to various embodiments of the disclosed technology.

In operation 410 of the flow chart 400, the RTL test point tool 300 receives, from the input database 305, an RTL (register-transfer-level) circuit design. The RTL circuit design may employ VHDL or the Verilog language.

In operation 420, the quick logic synthesis unit 310 performs a quick logic synthesis process on the RTL circuit design to generate a gate-level netlist. Quick logic synthesis is a streamlined or expedited process of logic synthesis aimed at generating a preliminary, fast, and often less-optimized netlist from an RTL design. It is typically used for rapid prototyping or design exploration. Compared to full logic synthesis described previously, it does not include detailed technology-dependent optimizations such as gate sizing. Therefore, the logic generated during quick logic synthesis may not be fully optimized for timing, area, or power even though basic or essential technology-independent logic optimizations such as eliminating unused logic and performing basic Boolean simplifications may be performed.

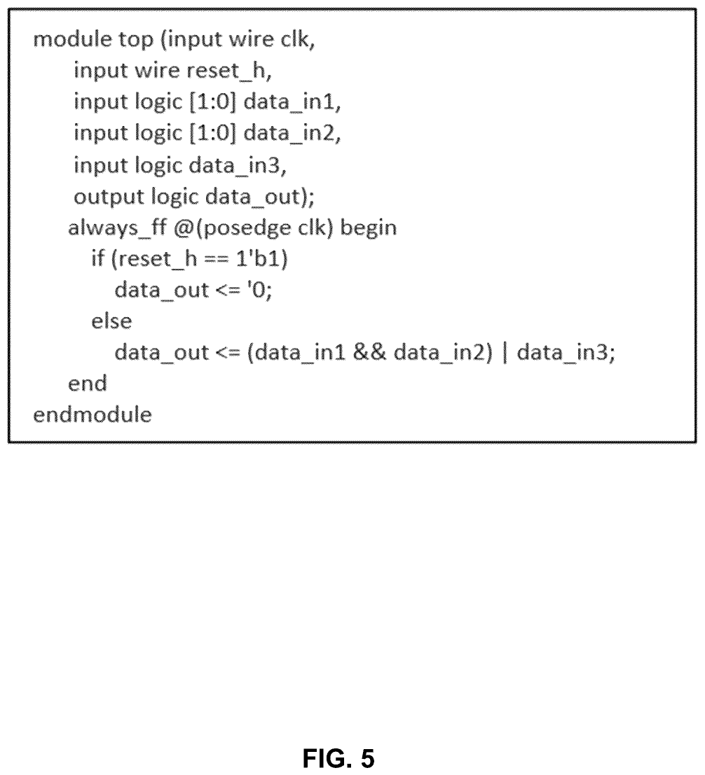

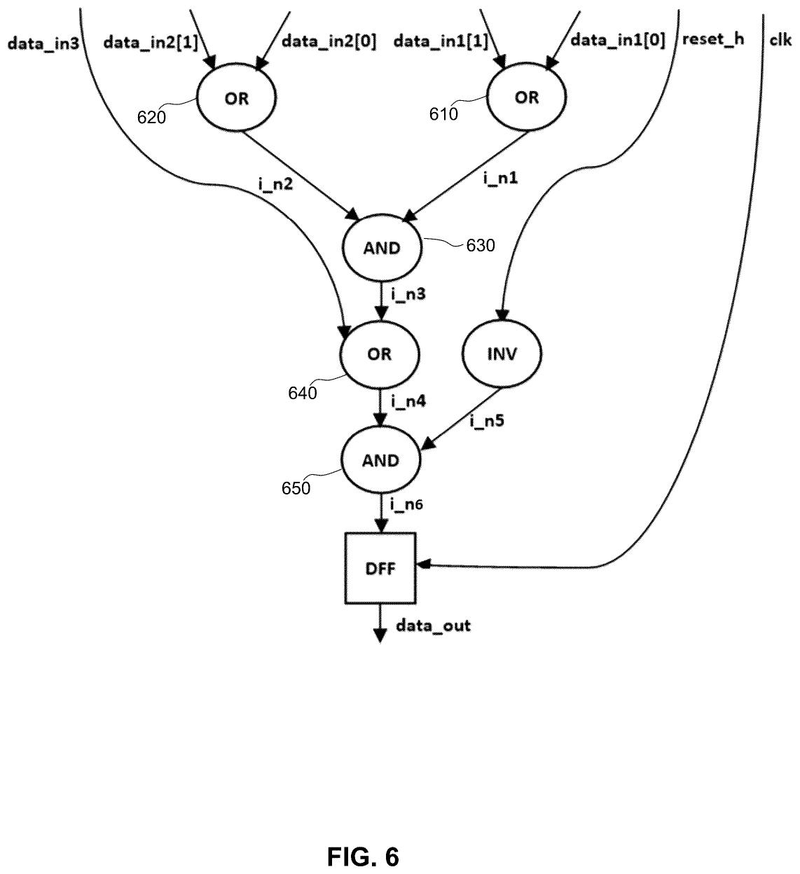

The disclosed technology may employ various forms of quick logic synthesis that skip or simplify optimization steps differently. Additionally, the disclosed technology may replace technology mapping with mapping to a generic library. According to some embodiments of the disclosed technology, the quick logic synthesis unit 310 may first parse the RTL circuit design to analyze its structure and meaning. A parse tree may be generated as a result, which is a hierarchical tree structure representing the syntactic structure of the hardware description language (HDL) code for the RTL circuit design. The quick logic synthesis unit 310 may then perform compilation to convert the elaborated RTL description into an expanded and flat representation that can be directly translated into logic gates and Boolean expressions. The generated gate-level netlist may be a flattened netlist which can be represented as a directed acyclic graph (DAG). In a directed acyclic graph, the vertices are the gate objects representing the instances of the generic primitive cell library and edges are the gate nodes connecting a gate to another gate object. FIG. 5 illustrates an example of a small piece of System Verilog RTL code. The example in FIG. 5 is transformed into a flattened DAG representation as shown in FIG. 6. All edges named “i_n#” are internal nodes (nets) created to connect a pin of a gate to another gate.

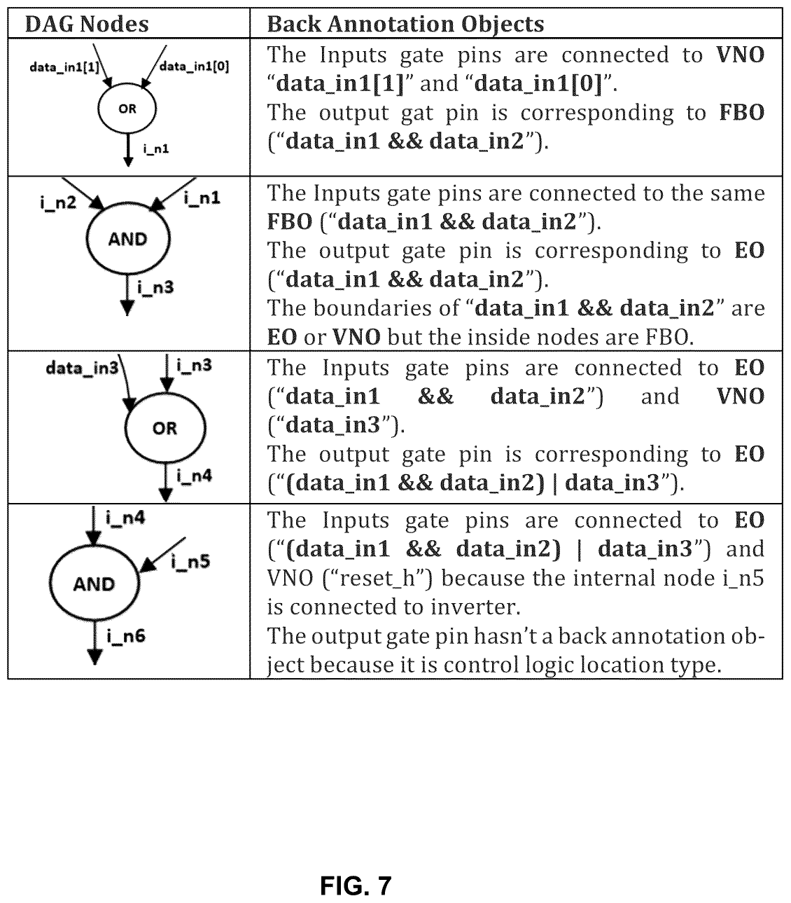

Referring back to FIG. 4, in operation 430, the back-annotation unit 320 back-annotates gate-level nodes in the gate-level netlist to corresponding locations in the RTL circuit design. The back-annotation unit 320 can use information derived during the quick logic synthesis process in the previous operation 420. An example of such information is the parse tree. The parse tree breaks down the HDL code into its constituent parts, showing the relationships between operators, variables, and expressions, facilitating subsequent steps in the synthesis process, such as structural decomposition and behavioral optimization. It is thus an important intermediate representation in the logic synthesis process. An edge (gate pin) of a directed acyclic graph (DAG) representation can be mapped to its equivalent parse-tree node. It should be noted that the back-annotation unit 320 may map one location at the gate-level netlist to multiple RTL locations (expressions, control statements, . . . ). A back-annotated RTL location may be an RTL object. FIG. 7 illustrates a one-to-one correspondence between some of the DAG nodes shown in FIG. 6 and the RTL back-annotated locations shown in FIG. 5 which are highlighted. For OR gate 610, the two input pins are mapped (back-annotated) to “data_in1[1]” and “data_in1[0]” in the RTL code, and the output pin of the OR gate 610 is mapped to a node (“i_n1”) inside “(data_in1 && data_in2)” in the RTL code. For AND gate 630, the two input pins are also the output pins of the two OR gates 610-620 correspond to the two nodes (“i_n1” & “i_n2”) inside “(data_in1 && data_in2)” in the RTL code, and the output pin is mapped to a node (“i_n3”) at the boundary of “(data_in1 && data_in2)” in the RTL code. For OR gate 640, one of the two input pins is the output pin of the AND gate 630 corresponding to the boundary node (“i_n3”), the other input pin is mapped to “data_in3” in the RTL code, and the output pin is mapped to a node (“i_n4”) at the boundary of “(data_in1 && data_in2) |data_in3” in the RTL code. For AND gate 650, one of the two input pins is the output pin of the OR gate 640 corresponding to the boundary node (“i_n4”), the other input pin is mapped to “reset_h” in the RTL code, and the output pin is mapped to the control logic “if-else” in the RTL code.

Referring back to FIG. 4, in operation 440, the editable area determination unit 330 determines editable areas in the gate-level netlist based on the previous back-annotating operation. In effect, the editable area determination unit 330 divides the gate-level netlist into two types of regions, editable and non-editable regions. Editable regions are testable gate-level nodes that can be back annotated to RTL locations associated with editable RTL constructs. The non-editable regions are gate-level nodes that are mapped to RTL locations associated with non-editable RTL constructs. Whether a type of RTL constructs is treated as editable or not may not be the same for various implementations of the disclosed technology.

In some embodiments of the disclosed technology, the following two types of RTL constructs are defined as editable: RTL nets to which gate-level nodes are directly mapped, and RTL expression or sub-expression boundaries to which gate-level nodes are directly mapped. The former may also be referred to as visible net object (VNO) and the latter may also be referred to as expression object (EO). Visible net objects include nets, port and pins declared and visible at RTL. A visible net object corresponds to, for example, an output expression at an instance input pin, an input or an output of control logic (mux or equivalent) connected to visible RTL nets. Expression objects include inputs and outputs of RTL expressions and sub-expressions. An expression object corresponds to, for example, a local net created by quick logic synthesis that is connected to an expression output. In these embodiments of the disclosed technology, both logic inside functional blocks to which gate-level nodes are mapped and the control logic to which gate-level nodes are mapped are defined as non-editable RTL constructs. The former may also be referred to as functional block object (FBO). Adders, comparators, multipliers, shifters, and logical operators are examples of functional blocks. Functional block objects correspond to, for example, nodes within adders, subtractors, comparators, shifters, and multiple stages of logical operators. The control logic includes sequential control statements that include if-then-else and case constructs. In FIG. 7, “data_in1[1]”, “data_in1[0]”, “data_in3”, and “reset_h” are indicated as VNO; the boundary nodes (“i_n3” & “i_n4”) are indicated as EO; and the two nodes (“i_n1” & “i_n2”) inside “data_in1 && data_in2” are indicated as FBO. Thus, the input pins of the OR gates 610-620, the gate pins corresponding to “data_in3” and “reset_h”, and the output pins of the AND gate 630 and the OR gate 640 correspond to editable areas. The input pins of the AND gate 630 and the output pin of the AND gate 650 correspond to non-editable areas.

In some other embodiments of the disclosed technology, in addition to RTL constructs that are visible net objects and expression objects, those belonging to functional block objects may be defined as editable RTL constructs. As such, the input pins of the AND gate 630 in FIG. 6 correspond to editable areas as well.

In still some other embodiments of the disclosed technology, RTL constructs that are visible net objects, expression objects, functional block objects, and control logic may all be defined as editable RTL constructs. As such, all the gate pins show in FIG. 7 correspond to editable areas. An example of non-editable RTL constructs may be some hard macros corresponding to pre-synthesized library cells.

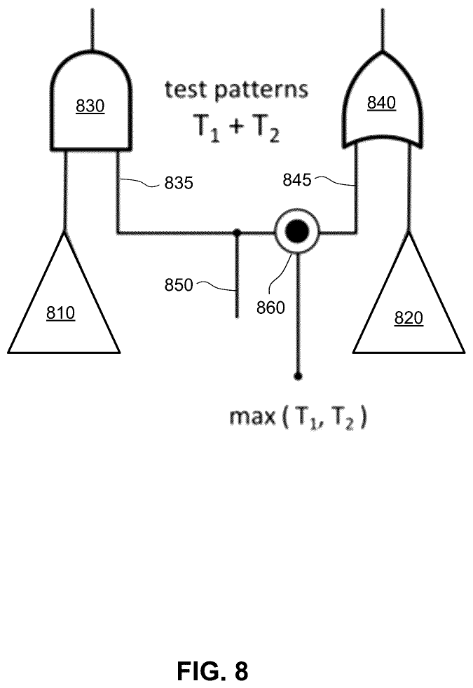

Referring back to FIG. 4, in operation 450, the test point analysis unit 340 performs a test point analysis process on the gate-level netlist to determine gate-level locations for test point insertion in the editable areas. The test point analysis unit 340 may use various test point analysis techniques. Test points may include conflict-aware test points, LBIST (logic bult-in self-test) test points, or hybrid test points. FIG. 8 illustrates an example of conflict-aware test points. To propagate faults from a cone of logic 810 through AND gate 830, input 835 of the AND gate 830 must be set to 1. Similarly, to propagate faults from a cone of logic 820, input 845 of OR gate 840 must assume the value of 0. The two different requirements result in conflicting values at stem 850, dictating that faults in the logic 810 and the logic 820 cannot be detected by the same test pattern, and the resultant pattern count is equal to T1+T2. In general, conflicts between logic values within a given test stimulus occur due to incompatible decisions made by ATPG during backward justification or fault propagation preceded by fault excitation. Simultaneous detection of these faults would be possible by placing a control test point on one of the stem branches to resolve the conflict. In FIG. 8, for example, a control test point 860 on the right branch allows 0-controllability of this net. As a result, the number of test patterns becomes max {T1, T2}. If T1≈T2, then the pattern count can be approximately halved. Hence, test points placed in this type of locations, referred to as conflict-aware test points, can significantly reduce the overall pattern count.

An important feature of conflict-aware test point analysis is to identify and resolve conflicts between ATPG-produced signals. An example test point analysis process for reducing ATPG pattern counts and scan data volume is thus also referred to as a conflict identification process in C. Acero, D. Feltham, Y. Liu, E. Moghaddam, N. Mukherjee, M. Patyra, J. Rajski, S. M. Reddy, Jerzy Tyszer, Justyna Zawada, “Embedded deterministic test points,” IEEE Transactions on Very Large-Scale Integration (VLSI) Systems, 2949-2961, 2017 (referred to as “Acero” thereinafter). Acero is incorporate herein by reference. In the process, two pairs of metrics are gradually assigned to internal lines of a circuit. The first pair, bₓ and Bₓ, represent the number of 0s and 1s, respectively, needed on net x to enable propagation of faults through all relevant gates; and the second pair, fₓ and Fₓ, represent the number of forward-implied 0s and 1s, respectively, on line x due to earlier backward justifications. One way to measure the degree of conflicts occurring at a given line x is to employ two values derived based on the two pairs of metrics: cₓ=min{bₓ,Fₓ} and Cₓ=min{Bₓ, fₓ} . They estimate the amount of inconsistency between fault propagation conditions and the corresponding forward-implied values. In particular, the value of cₓ gives the degree of conflict between the number bₓ of 0s needed to propagate faults through certain gates and the number Fₓ of 1s that should propagate forward through net x.

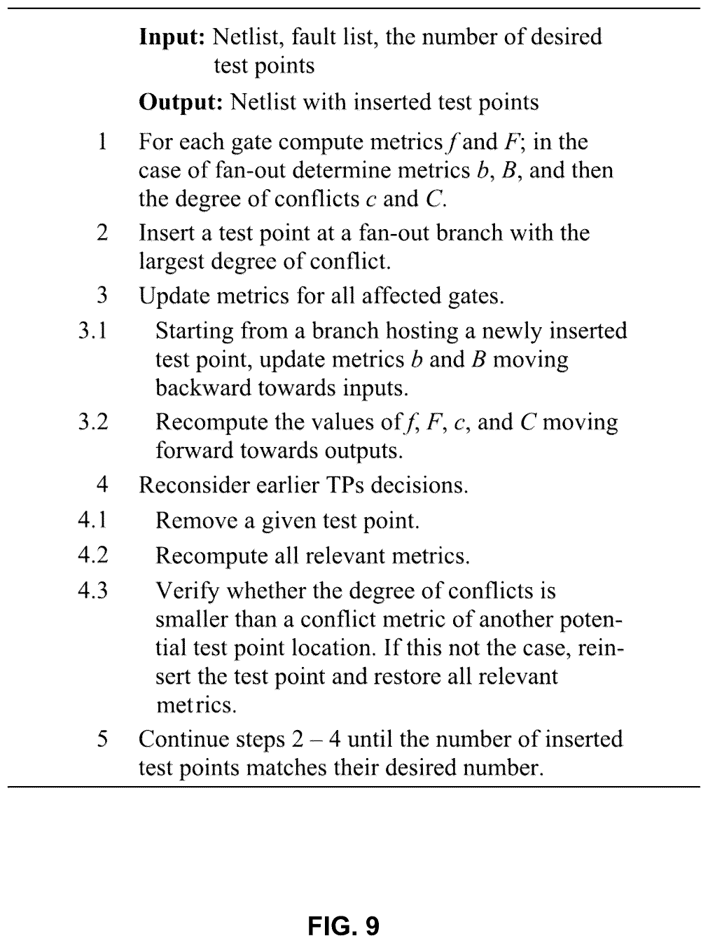

To identify such sites, the test point analysis unit 340 can compute metrics b, B, f, and F by traversing, in a gate-level order and in a single pass, the gate-level netlist. Starting from the first level, metrics f and F are determined for each gate by using Eqs. (3)-(7) in Acero. Eqs. (8) and (9) in Acero are employed whenever a fan-out is encountered. In this case, however, the number of blocked faults due to 1s and 0s occurring at a given branch can be computed to find metrics b and B to be subsequently employed, through Egs. (10) and (11) in Acero, to assess the degree of conflicts observed at the fan-out branches. As a result, this single-pass traversal can yield a sorted, in a descending order, list of conflicts represented by either cₓ or Cₓ. With all conflicts being sorted, the test point analysis unit 340 can repeatedly remove the top of the list, i.e., the largest degree conflict cₓ or Cₓ, and insert the corresponding AND or OR control test point, respectively, at a designated fanout branch x. Since a new control test point may affect metrics of all items currently on the list, the test point analysis unit 340 can update the metrics at the end of each iteration. The procedure may iterate until the number of inserted test points matches the desired and user-defined number of test points that can be added into a design. FIG. 9 illustrates an example test point analysis for reducing ATPG pattern counts and scan data volume.

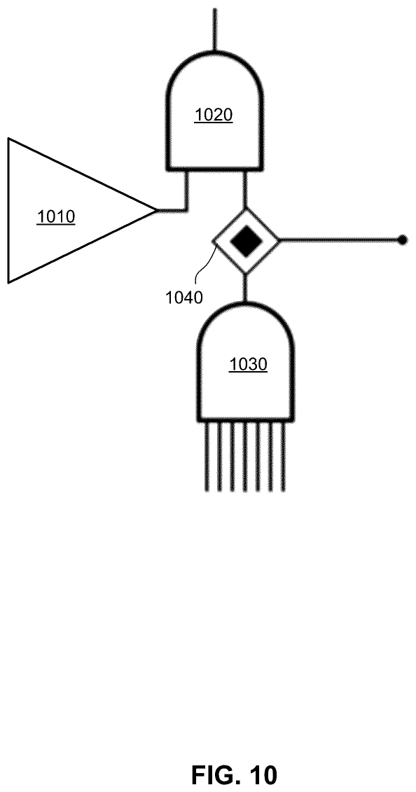

LBIST (logic bult-in self-test) test points are commonly used to make random resistant logic more testable. FIG. 10 illustrates an example of LBIST test points. To propagate faults in a cone of logic 1010 through an AND gate 1020, one needs to set an input 1025 of this gate to 1. With pseudorandom patterns driving an AND gate 1030, the probability of getting 1 on its output is relatively low. This is why having a control test point 1040 between the AND gates 1020 and 1030 may resolve this problem.

In a test point analysis process for determining LBIST test points, the test point analysis unit 340 can, for example, compute testability measures for every edge (gate-pins) of the directed acyclic graph (DAG) derived from the quick synthesis. The testability measures reflect the controllability and the observability measures of each gate-pin associated to a gate object. The test point analysis unit 340 can first initialize the controllability of primary and pseudo-primary inputs to 0.5, and the observability of primary and pseudo-primary outputs to 1. Then the test point analysis unit 340 can propagate them forward and backward through the gate-pin nodes. The computed testability measures allow identifying hard-to-detect faults at gate pins or gate-level nodes which can be utilized in the selection of suitable test points.

The paper, E. Moghaddam, N. Mukherjee, J. Rajski, J. Solecki, J. Tyszer, J. Zawada, “Logic BIST with Capture-Per-Clock Hybrid Test Points”, IEEE Transactions on Computer-Aided Design of Integrated Circuits and Systems, vol. 38, no. 6, pp. 1028-1041, 2019 (referred to as “Moghaddam” thereinafter), presents a hybrid test point technology designed to identify internal conflicts that preclude efficient ATPG-based test compaction and detection of random resistant faults. Moghaddam is incorporated herein by reference. The number of faults propagating through a net is one of the key factors used to identify the most suitable locations of hybrid test points. Metrics b and B described in Acero can also be regarded as the number of blocked faults, if a given line was set to 1 and 0, respectively. Besides metrics b and B, the hybrid conflict analysis in Moghaddam employs controllability/observability measures. Let pₓ and Pₓ be the probabilities of getting values of 0 and 1 at line x, respectively. The degree of conflict between a logic value enabling fault propagation and the probability of its occurrence at the same location is measured as: cₓ=−bₓ log₁₀ pₓ, Cₓ=−Bₓ log₁₀ Pₓ. The observation performance Ωₓ for line x is: Ωₓ=−Dₓ log₁₀ Oₓ. where Dₓ and Oₓ are the number of faults propagating through net x, and this line observability, respectively. A circuit is processed in a gate-level order in two major steps. First, the test point analysis unit 340 can compute controllabilities and observabilities for each net. Next, starting from the primary inputs, the test point analysis unit 340 can propagate faults forward. Subsequently performance of a candidate observation point is determined for each net using Eq. (6) in Moghaddam. The hybrid conflicts for CPs are computed according to (4) and (5) in Moghaddam. As a result, the test point analysis unit 340 can derive two lists representing the best locations for control and observation points which are sorted in descending order. An iteration process similar to the one in Acero can be performed. The details can be found in Moghaddam which is incorporated herein by reference.

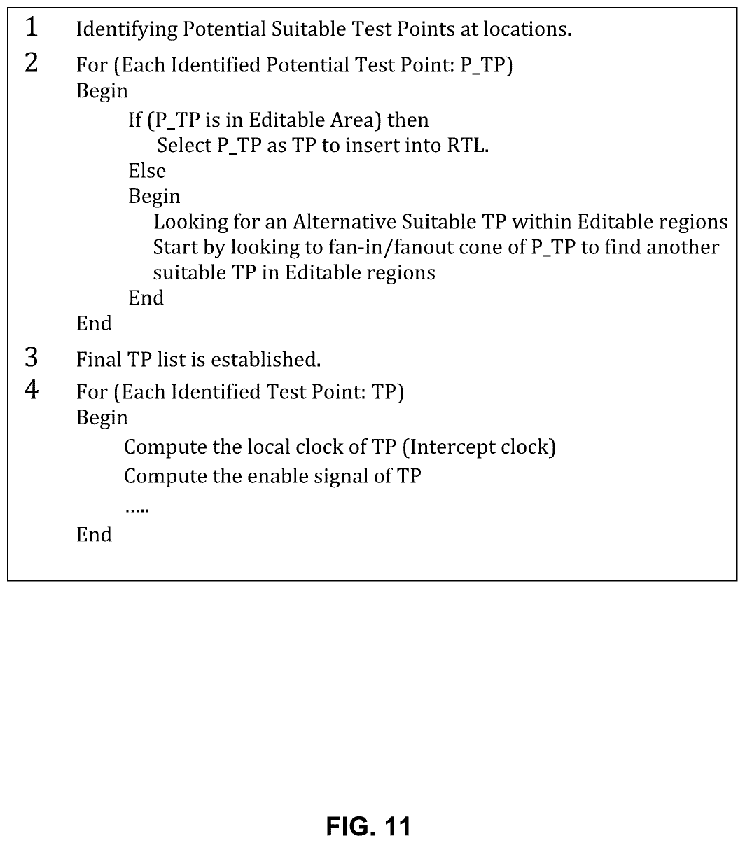

FIG. 11 illustrates an example of an overall test point analysis process that may be implemented according to various examples of the disclosed technology. The first operation may be performed by using various conventional test point analysis techniques like those described above. When a potential suitable test point is not in editable areas, the test point analysis unit 340 may also look for an alternative suitable test point within editable regions by looking to fan-in/fanout cone of the potential suitable test point to find another suitable test point in editable regions.

In addition to gate-level locations for test point insertion, the test point analysis unit 340 can also identify necessary information associated with every test point, such as clock domain, the local clock intercept node, test enable signal, pin-path name for the test point location, etc.

Referring back to FIG. 4, in operation 460, the RTL test point location determination unit 350 can determine RTL locations for test point insertion in the RTL circuit design corresponding to the gate-level locations for test point insertion determined in the operation 450 based on the back-annotating operation 430. The location for every test point is typically associated with a pin pathname within the gate-level netlist. Subsequently, the RTL test point location determination unit 350 can transform this gate-level pin to its equivalent RTL location, which can be within an expression (or sub-expression) boundary, visible RTL net, or within functional blocks. Additional information for determining the optimal RTL location may be extracted from the parse tree. The back annotation of a test point location at the gate-level may lead to multiple RTL locations. All RTL objects associated with the back-annotated RTL locations (reflecting test points list) may be grouped into unique views groups. This pre-processing step can simplify the uniquification process during test point insertion.

In operation 470, the RTL test point tool 300 can store information of the RTL locations for test point insertion for modifying the RTL circuit design in the output database 375.

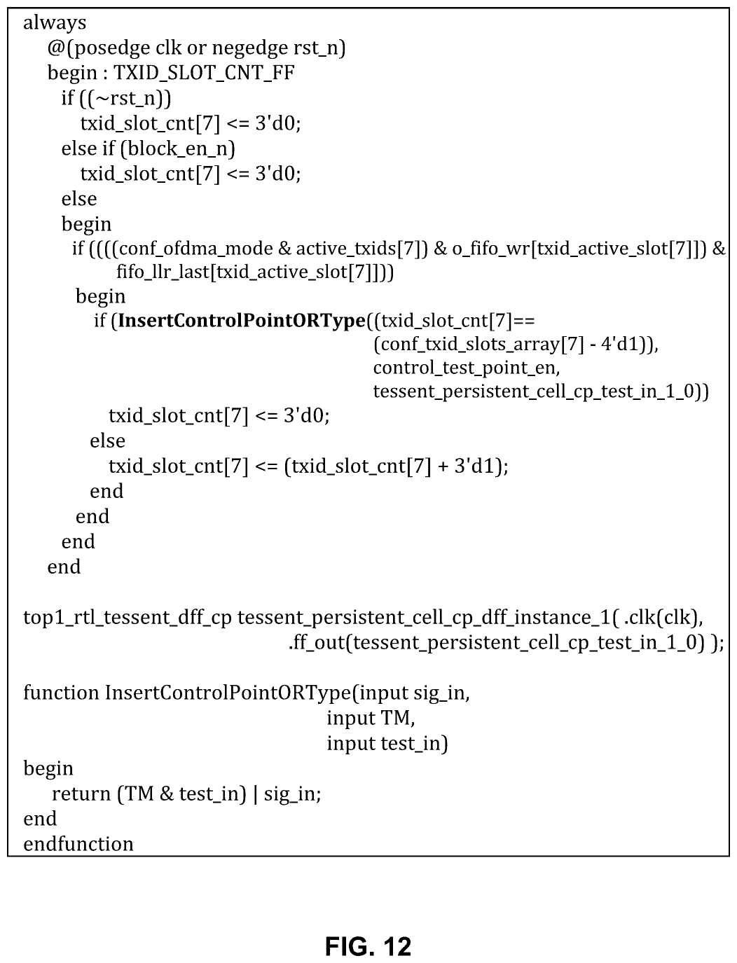

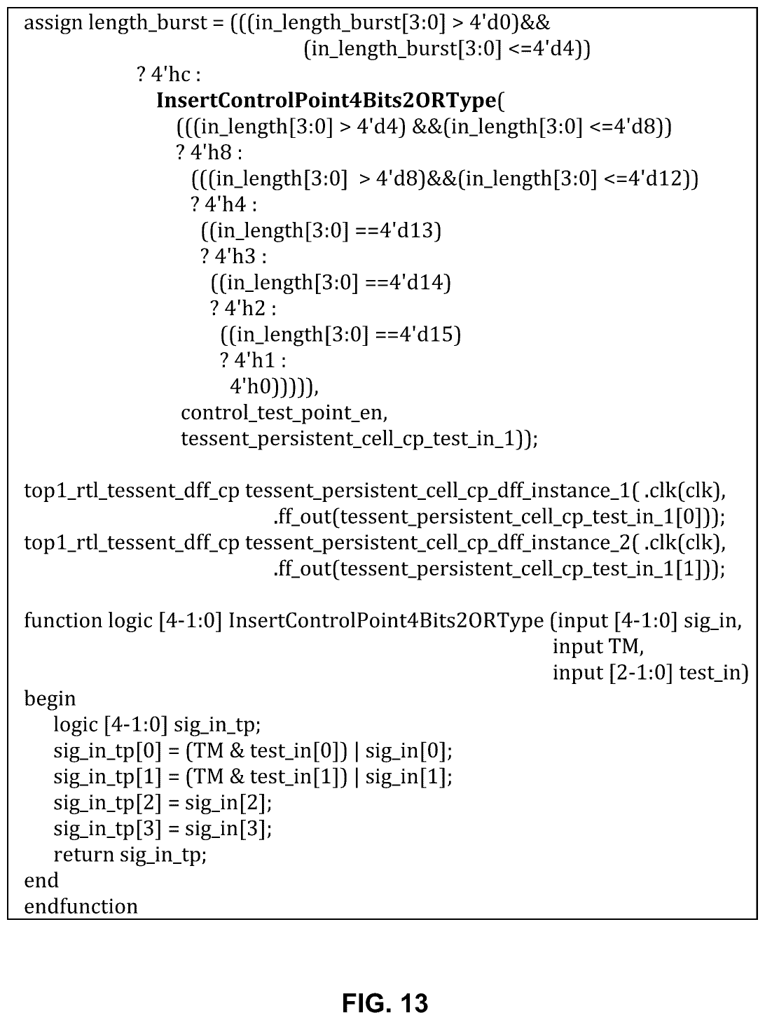

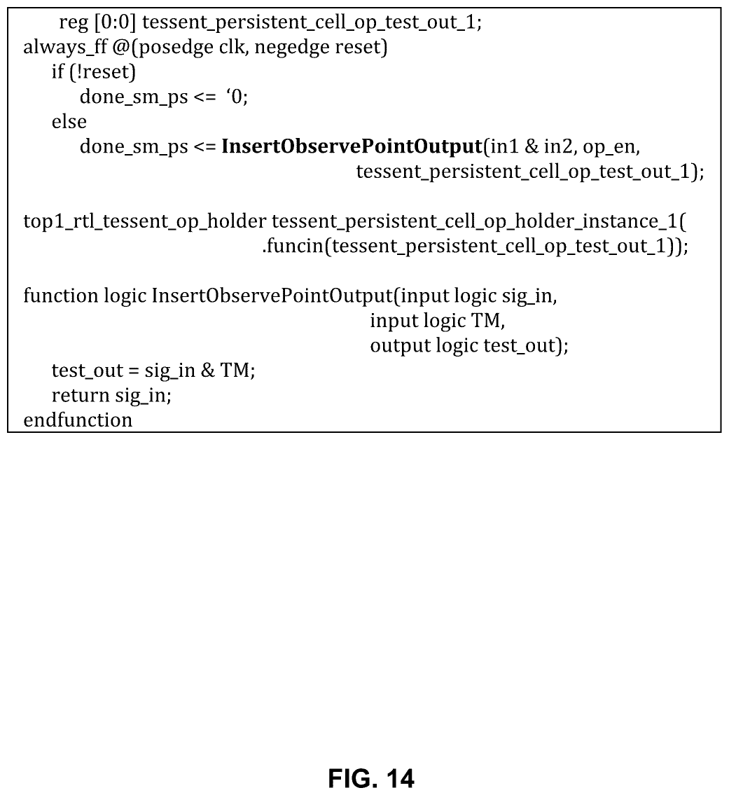

Optionally, in operation 480, the RTL test point insertion unit 360 inserts test points at the RTL locations for test point insertion to derive a modified RTL circuit design. The insertion process may be guided by the types of RTL constructs associated with the back-annotated RTL locations. Different insertion techniques may be used to introduce the control and observe logic for various RTL contexts. Function declaration is one of the common constructs in RTL and is optimized by logic synthesis tools. This technique can be used to isolate the RTL expression boundary (for the expression object (EO) type of back-annotated RTL locations) where the combinational logic that is part of a control/observation test point is inserted. Every expression inferred from gates abstraction can be a specific cone of logic. The concerned logic can have a 1-bit or multiple bits (bus) output. Within the framework of RTL test point insertion, multiple function declarations for each scenario can be predefined. They are defined as templates, and according to the logic cone associated with a test point, an instance of this template will be generated. For each Function Declaration Model, three versions may be pre-defined. FIG. 12 illustrates an example of a control test point (highlighted) inserted at a 1-bit output of a logical expression “(txid_slot_cnt[7]==(conf_txid_slots_array[7]−4′d1)”. FIG. 13 illustrates an example of two control test points inserted at the output of an expression of 4-bits. FIG. 14 illustrates an example of an observation test point inserted at the output of a 1-bit expression. The Instance “top1_rtl_tessent_op_holder” module is inserted in case an observation test point is identified at the boundary of an expression declared within a clocked always-statement.

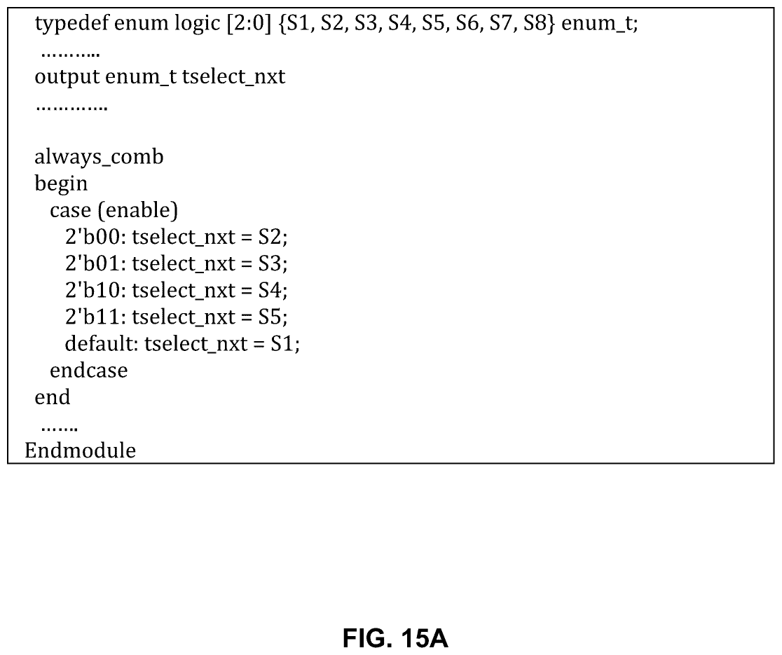

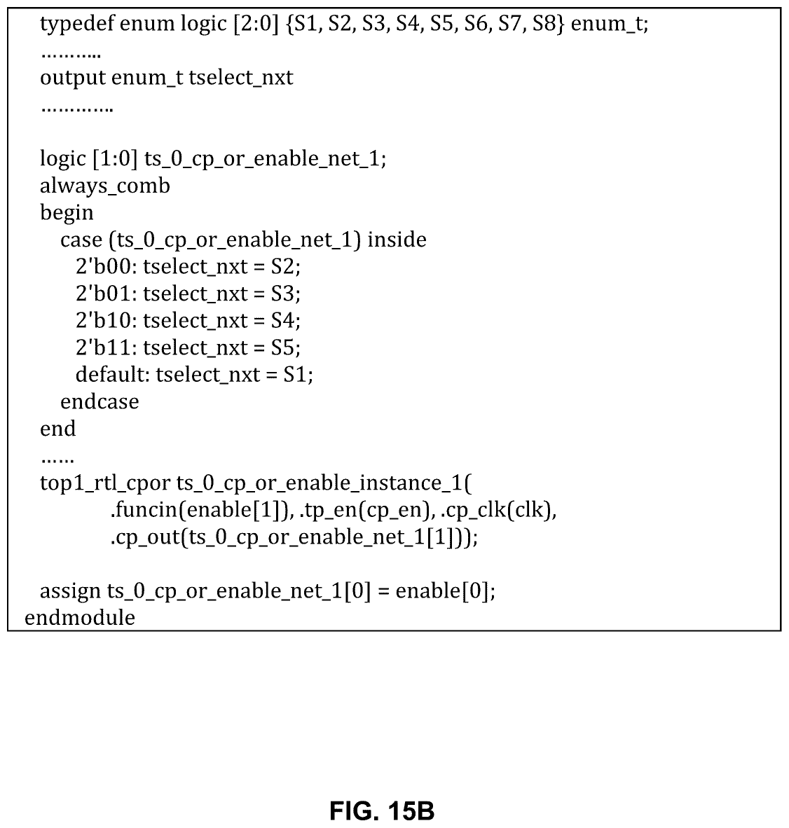

The RTL test point insertion unit 360 may employ a technique referred to as RTL structural insertion technique for the visible net object (VNO) type of back-annotated RTL locations. In this technique, only structural interception of visible net connections is used for a control test point, and connecting the visible net to a floating flip-flop is used for an observation test point. FIGS. 15A and 15B illustrate an example of an RTL design before and after a control test point is inserted into a visible net, respectively. In this case, the control test point is identified at an input of a gate pin of the case-statement (control logic), and the concerned gate pin is back annotated to “enable[1]” VNO.

Optionally, in operation 490, the full RTL logic synthesis tool 380 performs a full logic synthesis process on the modified RTL circuit design to generate a technology-mapped and fully optimized gate-level netlist. If the RTL test points still cannot meet the target in terms of total pattern count or overall test coverage targets, additional test points may be inserted into the technology-mapped and fully optimized gate-level netlist based on a further test point analysis process.

Optionally, in operation 495, the RTL complexity analysis unit 370 performs an RTL complexity analysis to provide information for designers to adjust the RTL circuit design The RTL complexity analysis unit 370 may employ standard Cyclomatic Complexity techniques. The cyclomatic complexity gives an upper bound for the number of functional patterns required to obtain branch coverage of the RTL code. This technique may be fine-tuned with hardware abstraction for every control statement within the RTL. Based on this measure, a simple heuristic can be developed to evaluate if the RTL design is suitable or not for RTL test point insertion.

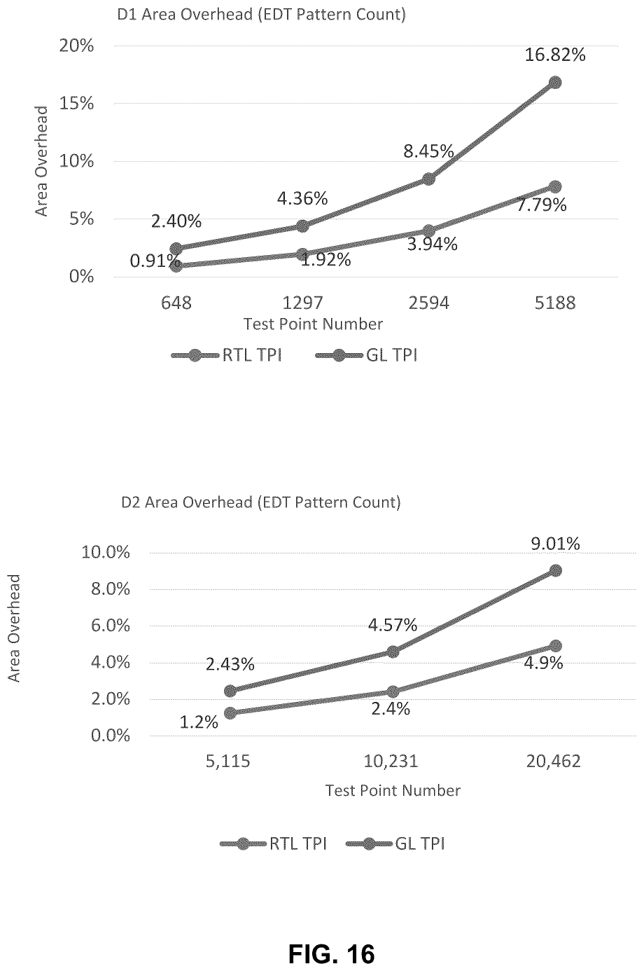

The disclosed technology employs quick logic synthesis, gate-level test point analysis, editable region partition and back annotation for RTL test point insertion. This allows designers to insert and verify test point insertion early in the design flow, reducing the complexity of verification and the impact on the overall design cycle while keeping the benefit of robust test point analysis at the gate level. For example, the disclosed technology enables one to verify some of the key DFT parameters such as test coverage and pattern count early in the design flow and take corrective measures for the outlier blocks. The insertion techniques used in this solution can also preserve the format (look-and-feel) of the original RTL as much as possible. FIG. 16 illustrates the benefits of RTL test point insertion in terms of total area overhead percentage for two industry designs D1 and D2. In each case, the top curve is for gate-level test point insertion and the bottom curve is for RTL test point insertion. For D1, the area overhead is evaluated after inserting test points equal to 2%, 4%, 8% and 16% of the total number of sequential elements in the design. Similarly, the area overhead for D2 after inserting test points equal to 2%, 4% and 8% of sequential elements are presented. The graphs show that the overall area overhead incurred for test points is less when inserted at RTL compared to the gate-level. This makes sense as synthesis tools have a much better opportunity to optimize the area overhead associated with test points when inserted at RTL, compared to gate-level insertion.

### CONCLUSION

Having illustrated and described the principles of the disclosed technology, it will be apparent to those skilled in the art that the disclosed embodiments can be modified in arrangement and detail without departing from such principles. In view of the many possible embodiments to which the principles of the disclosed technologies can be applied, it should be recognized that the illustrated embodiments are only preferred examples of the technologies and should not be taken as limiting the scope of the disclosed technology. Rather, the scope of the disclosed technology is defined by the following claims and their equivalents. We therefore claim as our disclosed technology all that comes within the scope and spirit of these claims.

What is claimed is:

1. A method, executed by at least one processor of a computer, comprising:
receiving an RTL (register-transfer-level) circuit design;
performing a quick logic synthesis process on the RTL circuit design to generate a gate-level netlist;
back-annotating gate-level nodes in the gate-level netlist to corresponding locations in the RTL circuit design;
determining editable areas in the gate-level netlist based on the back-annotating gate-level nodes;
performing a test point analysis process on the gate-level netlist to determine gate-level locations for test point insertion in the editable areas;
determining RTL locations for test point insertion in the RTL circuit design corresponding to the gate-level locations for test point insertion based on the back-annotating gate-level nodes; and
storing information of the RTL locations for test point insertion for modifying the RTL circuit design.

2. The method recited in claim 1, further comprising:
inserting test points at the RTL locations for test point insertion to derive a modified RTL circuit design; and
performing a full logic synthesis process on the modified RTL circuit design to generate a technology-mapped and fully optimized gate-level netlist.

3. The method recited in claim 2, further comprising:
inserting additional test points into the technology-mapped and fully optimized gate-level netlist based on a further test point analysis process.

4. The method recited in claim 1, further comprising:
performs an RTL complexity analysis based on the information of the RTL locations for test point insertion to provide information for designers to adjust the RTL circuit design; and
adjusting the RTL circuit design based on the information for designers to adjust the RTL circuit design.

5. The method recited in claim 1, wherein the quick Logic synthesis process comprises:
mapping to a generic library.

6. The method recited in claim 1, wherein the editable areas comprise gate-level nodes that are directly mapped to RTL nets and gate-level nodes that are directly mapped to RTL expression or sub-expression boundaries.

7. The method recited in claim 6, wherein the editable areas further comprise gate-level nodes that are mapped to RTL locations belonging to functional block objects.

8. The method recited in claim 1, wherein the gate-level netlist is flattened and represented as a Directed Acyclic Graph (DAG).

9. One or more computer-readable media storing computer-executable instructions for causing one or more processors to perform a method, the method comprising:
receiving an RTL (register-transfer-level) circuit design;
performing a quick logic synthesis process on the RTL circuit design to generate a gate-level netlist;
back-annotating gate-level nodes in the gate-level netlist to corresponding locations in the RTL circuit design;
determining editable areas in the gate-level netlist based on the back-annotating gate-level nodes;
performing a test point analysis process on the gate-level netlist to determine gate-level locations for test point insertion in the editable areas;
determining RTL locations for test point insertion in the RTL circuit design corresponding to the gate-level locations for test point insertion based on the back-annotating gate-level nodes; and
storing information of the RTL locations for test point insertion for modifying the RTL circuit design.

10. The one or more computer-readable media recited in claim 9, wherein the method further comprise:
inserting test points at the RTL locations for test point insertion to derive a modified RTL circuit design; and
performing a full logic synthesis process on the modified RTL circuit design to generate a technology-mapped and fully optimized gate-level netlist.

11. The one or more computer-readable media recited in claim 10, wherein the method further comprise:
inserting additional test points into the technology-mapped and fully optimized gate-level netlist based on a further test point analysis process.

12. The one or more computer-readable media recited in claim 9, wherein the method further comprise:
performs an RTL complexity analysis based on the information of the RTL locations for test point insertion to provide information for designers to adjust the RTL circuit design; and
adjusting the RTL circuit design based on the information for designers to adjust the RTL circuit design.

13. The one or more computer-readable media recited in claim 9, wherein the quick Logic synthesis process comprises:
mapping to a generic library.

14. The one or more computer-readable media recited in claim 9, wherein the editable areas comprise gate-level nodes that are directly mapped to RTL nets and gate-level nodes that are directly mapped to RTL expression or sub-expression boundaries.

15. The one or more computer-readable media recited in claim 14, wherein the editable areas further comprise gate-level nodes that are mapped to RTL locations belonging to functional block objects.

16. The one or more computer-readable media recited in claim 9, wherein the gate-level netlist is flattened and represented as a Directed Acyclic Graph (DAG).

17. A system, comprising:
one or more processors, the one or more processors programmed to perform a method, the method comprising:
receiving an RTL (register-transfer-level) circuit design;
performing a quick logic synthesis process on the RTL circuit design to generate a gate-level netlist;
back-annotating gate-level nodes in the gate-level netlist to corresponding locations in the RTL circuit design;
determining editable areas in the gate-level netlist based on the back-annotating gate-level nodes;
performing a test point analysis process on the gate-level netlist to determine gate-level locations for test point insertion in the editable areas;
determining RTL locations for test point insertion in the RTL circuit design corresponding to the gate-level locations for test point insertion based on the back-annotating gate-level nodes; and
storing information of the RTL locations for test point insertion for modifying the RTL circuit design.

18. The system recited in claim 17, wherein the method further comprise:
inserting test points at the RTL locations for test point insertion to derive a modified RTL circuit design; and
performing a full logic synthesis process on the modified RTL circuit design to generate a technology-mapped and fully optimized gate-level netlist.

19. The system recited in claim 17, wherein the editable areas comprise gate-level nodes that are directly mapped to RTL nets and gate-level nodes that are directly mapped to RTL expression or sub-expression boundaries.

20. The system recited in claim 19, wherein the editable areas further comprise gate-level nodes that are mapped to RTL locations belonging to functional block objects.
